(19) United States
(12) Patent Application Publication
(10) Pub. No.: US 2016/0032490 A1
(43) Pub. Date: Feb. 4, 2016

(54) TUNED MATERIALS, TUNED PROPERTIES, AND TUNABLE DEVICES FROM ORDERED OXYGEN VACANCY COMPLEX OXIDES

(71) Applicant: BOARD OF REGENTS, THE UNIVERSITY OF TEXAS SYSTEM, Austin, TX (US)

(72) Inventors: CHONGLIN CHEN, San Antonio, TX (US); CHUNRUI MA, San Antonio, TX (US); MING LIU, Xi'an (CN)

(21) Appl. No.: 14/724,459

(22) Filed: May 28, 2015

Related U.S. Application Data
(60) Provisional application No. 62/003,751, filed on May 28, 2014.

(51) Int. Cl. C30B 33/02; C30B 29/22; C30B 23/02; C30B 33/00; H01F 1/10; C30B 23/06

(52) U.S. Cl. CPC C30B 33/02; H01F 1/10; C30B 23/066; C30B 23/025; C30B 33/005; C30B 29/22

(57) ABSTRACT

A single-crystalline LnBM₂O_{5+δ} or LnBM₂O_{5.5+δ} compound is provided, which includes an ordered oxygen vacancy structure; wherein Ln is a lanthanide, B is an alkali earth metal, M is a transition metal, O is oxygen, and 0≦δ≦1. Methods of making and using the compound, and devices and compositions including same are also provided.

### CROSS REFERENCE TO RELATED APPLICATIONS

This application claims the benefit of U.S. Provisional Application No. 62/003,751, filed May 28, 2014. The entire contents of the aforementioned application is incorporated by reference in its entirety.

### STATEMENT OF FEDERALLY SPONSORED RESEARCH AND DEVELOPMENT

This invention was made with government support under Grant No. DE-FE0003780 awarded by the Department of Energy. The government has certain rights in the invention.

### FIELD OF THE INVENTION

This application relates to single-crystalline LaBaCo₂O_{5+δ} (LBCO) compounds, methods of making, and their use. In particular, the application relates to epitaxial LBCO thin films, methods of making, and their use.

### BACKGROUND

Cobalt oxides have been widely studied for many years due to their high chemical stability, excellent oxygen permeability, and many other unique physical chemistry properties for energy conversion, catalysts, sensors, and solid oxides fuel cells, etc. Kim, G. et al., Appl. Phys. Lett. 88, 024103, (2006); Liu, J. et al., Chem Mater 22, 799-802, (2010); Kim, Y. M. et al., Nat Mater 11, 888-894, (2012). Cobaltates also exhibit rich magnetic and electronic transport properties, ranging from paramagnetic to ferromagnetism to antiferromagnetism, from magnetic frustration to metal insulator transition and colossal magnetoresistance (CMR), and many others. Bhide et al. Physical Review B 12, 2832-2843, (1975); Fauth, F. et al., Eur Phys J B 21, 163-174, (2001); Goodenough, J. B., Journal of Physics and Chemistry of Solids 6, 287-297, (1958). These extraordinary phenomena are highly dependent upon the degrees of the freedom of the charge distribution, spin and orbital status, and the lattice structures. Barbey, L., et al., Mater Res Bull 27, 295-301, (1992); Maignan, A., et al. J Solid State Chem 142, 247-260, (1999). Among the cobalt oxide family, LaBaCo₂O_{5+δ} (LBCO) (0≦δ≦1) exhibit various unique physical properties because of the presence of A-site disordered and A-site ordered structures, due to the close ionic sizes of La and Ba. Nakajima, T., et al. J Phys Soc Jpn 74, 1572-1577, (2005); Rautama, E. L. et al., Chem Mater 20, 2742-2750, (2008); Rautama, E. L. et al., Chem Mater 21, 102-109, (2009). In the A-site disordered structure, La/Ba is distributed randomly in the A-sites of the perovskite structure. In the A-site ordered structure, La and Ba alternately occupy A-site positions to form the double perovskite structure, or the “112” crystal structures. Kundu, A. K. et al., Physical Review B 76, 184432, (2007). In the cobalt oxide systems, cobalt is known to exhibit three possible valences, Co²⁺, Co³⁺, or Co⁴⁺, and their combination valences.¹³ The valence status is associated with the oxygen content in the system. On the other hand, the cobaltate systems can exhibit several different coordinations from tetrahedral, pyramidal to octahedral, which makes them form various structures with a great flexibility of the oxygen frameworks. Raveau, B. Philos Transact A Math Phys Eng Sci 366, 83-92, (2008). Oxygen nonstoichiometry in these cobaltate compounds therefore is a very crucial parameter for tuning their physical properties. Seikh, M. M. et al., Chem Mater 20, 231-238, (2008). These embodiments offer a great opportunity to fabricate novel multifunctional materials with designable physical properties. For instance, the processing conditions and post annealing treatments were shown to alter dramatically the transition temperatures, T_{cc}, in ferroelectric/ferromagnetic/superconductive films. Haeni, J. H. et al., Nature 430, 758-761, (2004); Burns, G. & Dacol, F. H., Physical Review B 28, 2527-2530, (1983). Recently, we have successfully fabricated and systematically studied the highly epitaxial double perovskite LaBaCo₂O_{5+δ} systems and observed various anomalous physical phenomena such as giant magnetoresistance effect, superfast chemical dynamics, strong interface charge/orbital coupling behaviors, etc. Liu, M. et al., Appl. Phys. Lett. 96, 132106, (2010); Liu, M. et al., Acs Appl Mater Inter 4, 5524-5528, (2012); Ma, C. R. et al., Appl. Phys. Lett. 101, 021602, (2012); Ma, C. R. et al., Acs Appl Mater Inter 5, 451-455, (2013); Liu, J. et al., Appl. Phys. Lett. 97, 094101, (2010). Especially, the achievement of fabricating an ordered oxygen vacancy structure in the highly epitaxial (La,Sr)CoO_{3-δ} thin films with various post-annealing treatments has opened up a new avenue for the studies of the ordered oxygen vacancy structures and their effects on their physical properties. Donner, W. et al. Chem Mater 23, 984-988, (2011).

The present inventors have found, for the first time, the tunable properties from ferromagnetic to ferroelectric by tailoring the oxygen vacancy structures in the LaBaCo₂O_{5+δ} thin films. These new findings will open up a new avenue to realize room temperature and controllable multiferroic material systems by defect-engineered materials design and new functional materials integration.

### BRIEF DESCRIPTION OF THE SEVERAL EMBODIMENTS

It is to be understood that both the foregoing general description of the embodiments and the following detailed description are exemplary, and thus do not restrict the scope of the embodiments.

In some embodiments, provided herein is a new approach to tune the LBCO thin film from ferromagnetic properties to ferroelectric properties. The magnetoelectric response has been achieved at the room temperature with a large single phase magnetoelectric coupling coefficient up to 92.8 mV/cmOe. The unusual phase transition from the ferromagnetic-metallic (FM-M) phase to ferromagnetic-insulating ferroelectric (FM-I-FE) phases is attributed to the ordered oxygen vacancy structure. This indicates that the ordered oxygen vacancy structure and local asymmetries play an unusual key role in facilitating ferroelectric polarization. These findings may open up a new avenue for developing new multiferroic materials and will pave the way for tailoring the material microstructures to tune their properties for the new tunable device development.

In one embodiment, a single-crystalline LnBM₂O_{5+δ} or LnBM₂O_{5.5+δ} compound is provided, comprising an ordered oxygen vacancy structure; wherein

Ln is a lanthanide,

B is an alkali earth metal,

M is a transition metal,

O is oxygen, and

0≦δ>1.

In another embodiment, a composition is provided, comprising the one or more of the compounds described herein in epitaxial contact with a single-crystalline substrate.

In another embodiment, a single-crystalline LnBM₂O_{5+δ} or LnBM₂O_{5.5+δ} compound is provided, δ being ≧0 and ≦1, produced by a process comprising:

forming, on a single-crystalline substrate, a thin film comprising Ln, B, M, and O, wherein Ln is a lanthanide, B is an alkali earth metal, M is a transition metal, and O is oxygen;

annealing said thin film in an oxygen-containing gas, to form an oxygen-annealed film;

annealing said oxygen-annealed film under vacuum, and cooling.

In another embodiment, a method is provided, comprising:

forming, on a single-crystalline substrate, a thin film comprising Ln, B, M, and O, wherein Ln is a lanthanide, B is an alkali earth metal, M is a transition metal, and O is oxygen;

annealing said thin film in an oxygen-containing gas, to form an oxygen-annealed film;

annealing said oxygen-annealed film under vacuum, and cooling;

to produce a single-crystalline LnBM₂O_{5+δ} or LnBM₂O_{5.5+δ} compound, δ being ≧0 and ≦1.

In another embodiment, a single-crystalline LnBM₂O_{5+δ} or LnBM₂O_{5.5+δ} compound is provided, δ being ≧0 and ≦1, produced by a process comprising:

forming, on a single-crystalline substrate, a thin film comprising Ln, B, M, and O, wherein Ln is a lanthanide, B is an alkali earth metal, M is a transition metal, and O is oxygen;

annealing said thin film under vacuum, and cooling.

In another embodiment, a method is provided, comprising:

forming, on a single-crystalline substrate, a thin film comprising Ln, B, M, and O, wherein Ln is a lanthanide, B is an alkali earth metal, M is a transition metal, and O is oxygen;

annealing said thin film under vacuum, and cooling;

to produce a single-crystalline LnBM₂O_{5+δ} or LnBM₂O_{5.5+δ} compound, δ being ≧0 and ≦1.

In another embodiment, a single-crystalline LnBM₂O_{5+δ} or LnBM₂O_{5.5+δ} compound is provided, δ being ≧0 and ≦1, produced by a process comprising:

forming, on a single-crystalline substrate, a thin film comprising Ln, B, M, and O, wherein Ln is a lanthanide, B is an alkali earth metal, M is a transition metal, and O is oxygen; annealing said thin film in an oxygen-containing gas, and cooling.

In another embodiment, a method is provided, comprising:

forming, on a single-crystalline substrate, a thin film comprising Ln, B, M, and O, wherein Ln is a lanthanide, B is an alkali earth metal, M is a transition metal, and O is oxygen;

annealing said thin film in an oxygen-containing gas, and cooling,

to produce a single-crystalline LnBM₂O_{5+δ} or LnBM₂O_{5.5+δ} compound, δ being ≧0 and ≦1.

In another embodiment, a multiferroic device is provided, comprising one or more of the compounds described herein.

Other objects, features and advantages of the present invention will become apparent from the following detailed description. It should be understood, however, that the detailed description and the specific examples, while indicating specific embodiments of the invention, are given by way of illustration only, since various changes and modifications within the spirit and scope of the invention will become apparent to those skilled in the art from this detailed description.

### BRIEF DESCRIPTION OF THE DRAWINGS

The accompanying drawings form part of the present specification and are included to further demonstrate certain embodiments, which are not intended to be limiting, of the present invention. The invention may be better understood by reference to one or more of these drawings in combination with the detailed description of the specification embodiments presented herein.

FIG. 1 is (a) X ray diffraction θ-2θ scan of LBCO films prepared under oxygen annealing atmosphere. (b) X ray diffraction θ-2θ scan of LBCO films prepared under vacuum annealing atmosphere (c) Rocking curve measurement around (001) and (002) of LBCO thin film prepared under oxygen and vacuum annealing atmosphere, respectively.

FIG. 2 is Reciprocal space maps of LBCO thin film prepared under vacuum annealing (a-c) LBCO (002) and Nb:STO (001); LBCO (106) and Nb:STO (103); LBCO (016) and Nb: STO (013);and treated in oxygen (d-f) LBCO (001) and Nb:STO (001); LBCO (103) and Nb: STO (103); LBCO (013) and Nb: STO (013), respectively.

FIG. 3 is Ferroelectric hysteresis loop of vacuum annealed LBCO thin film on Nb: STO substrate. The inset (a) is Dielectric constant and loss as a function of frequency (b) Current as a function of applied voltage and applied voltage direction.

FIG. 4 is the Piezo Response of vacuum annealed LBCO thin film. (a) and (b) are the amplitude and phase images under +5V dc bias, respectively. (c) and (d) are the response of amplitude and phase when −5V dc bias is applied to the sample.

FIG. 5 is ZFC and FC magnetization of LBCO film with oxygen annealing (OA) and vacuum annealing (VA). The inset is the magnetic hysteresis loop measurement for these two films.

FIG. 6 is H_{dc} dependence of the in-plane magnetoelectric coefficient for the vacuum annealed LBCO thin film.

### DETAILED DESCRIPTION OF THE SEVERAL EMBODIMENTS

Reference will now be made in detail to embodiments of the invention which, together with the drawings and the following examples, serve to explain the principles of the invention. These embodiments describe in sufficient detail to enable those skilled in the art to practice the invention, and it is understood that other embodiments may be utilized, and that structural, biological, and chemical changes may be made without departing from the spirit and scope of the present invention. Unless defined otherwise, all technical and scientific terms used herein have the same meanings as commonly understood by one of ordinary skill in the art.

The use of the word “a” or “an” when used in conjunction with the term “comprising” in the claims and/or the specification may mean “one,” but it is also consistent with the meaning of “one or more,” “at least one,” and “one or more than one.”

Throughout this application, the term “about” is used to indicate that a value includes the standard deviation of error for the device or method being employed to determine the value.

The use of the term “or” in the claims is used to mean “and/or” unless explicitly indicated to refer to alternatives only or the alternatives are mutually exclusive, although the disclosure supports a definition that refers to only alternatives and “and/or.”

As used in this specification and claim(s), the words “comprising” (and any form of comprising, such as “comprise” and “comprises”), “having” (and any form of having, such as “have” and “has”), “including” (and any form of including, such as “includes” and “include”) or “containing” (and any form of containing, such as “contains” and “contain”) are inclusive or open-ended and do not exclude additional, unrecited elements or method steps.

In one embodiment, a single-crystalline LnBM₂O_{5+δ} or LnBM₂O_{5.5+δ} compound is provided, comprising an ordered oxygen vacancy structure; wherein

Ln is a lanthanide,

B is an alkali earth metal,

M is a transition metal,

O is oxygen, and

0≦δ≦1.

In another embodiment, a composition is provided, comprising the one or more of the compounds described herein in epitaxial contact with a single-crystalline substrate.

In another embodiment, a single-crystalline LnBM₂O_{5+δ} or LnBM₂O_{5.5+δ} compound is provided, δ being ≧0 and ≦1, produced by a process comprising:

forming, on a single-crystalline substrate, a thin film comprising Ln, B, M, and O, wherein Ln is a lanthanide, B is an alkali earth metal, M is a transition metal, and O is oxygen;

annealing said thin film in an oxygen-containing gas, to form an oxygen-annealed film;

annealing said oxygen-annealed film under vacuum, and cooling.

In another embodiment, a method is provided, comprising:

forming, on a single-crystalline substrate, a thin film comprising Ln, B, M, and O, wherein Ln is a lanthanide, B is an alkali earth metal, M is a transition metal, and O is oxygen;

annealing said thin film in an oxygen-containing gas, to form an oxygen-annealed film;

annealing said oxygen-annealed film under vacuum, and cooling;

to produce a single-crystalline LnBM₂O_{5+δ} or LnBM₂O_{5.5+δ} compound, δ being ≧0 and ≦1.

In another embodiment, a single-crystalline LnBM₂O_{5+δ} or LnBM₂O_{5.5+δ} compound is provided, δ being ≧0 and ≦1, produced by a process comprising:

forming, on a single-crystalline substrate, a thin film comprising Ln, B, M, and O, wherein Ln is a lanthanide, B is an alkali earth metal, M is a transition metal, and O is oxygen;

annealing said thin film under vacuum, and cooling.

In another embodiment, a method is provided, comprising:

forming, on a single-crystalline substrate, a thin film comprising Ln, B, M, and O, wherein Ln is a lanthanide, B is an alkali earth metal, M is a transition metal, and O is oxygen;

annealing said thin film under vacuum, and cooling; to produce a single-crystalline LnBM₂O_{5+δ} or LnBM₂O_{5.5+δ} compound, δ being ≧0 and ≦1.

In another embodiment, a single-crystalline LnBM₂O_{5+δ} or LnBM₂O_{5.5+δ} compound is provided, δ being ≧0 and ≦1, produced by a process comprising:

forming, on a single-crystalline substrate, a thin film comprising Ln, B, M, and O, wherein Ln is a lanthanide, B is an alkali earth metal, M is a transition metal, and O is oxygen; annealing said thin film in an oxygen-containing gas, and cooling.

In another embodiment, a method is provided, comprising: forming, on a single-crystalline substrate, a thin film comprising Ln, B, M, and O,

wherein Ln is a lanthanide, B is an alkali earth metal, M is a transition metal, and O is oxygen;
annealing said thin film in an oxygen-containing gas, and cooling,
to produce a single-crystalline LnBM₂O_{5+δ} or LnBM₂O_{5.5+δ} compound, δ being ≧0 and ≦1.

In another embodiment, a multiferroic device is provided, comprising one or more of the compounds described herein.

Referring to the formulas LnBM₂O_{5+δ} and LnBM₂O_{5.5+δ}, so long as Ln is a lanthanide, B is an alkali earth metal, M is a transition metal, O is oxygen, and 0≦δ≦1, the composition is not particularly limited.

In some embodiments, Ln is La, Pr, Nd, Sm, or Gd, or a combination of two or more thereof.

In some embodiments, B is Ba, Sr, or Ca, or a combination of two or more thereof.

In some embodiments, M is Co, Mn, Fe, or Ni, or a combination of two or more thereof.

In some embodiments, Ln is a lanthanide, B is Ba, M is Co, and O is oxygen.

So long as 0≦δ≦1, the value of δ is not particularly limited. This range includes all values and subranges therebetween, including, for example, 0, 0.01, 0.02, 0.03, 0.04, 0.05, 0.06, 0.07, 0.08, 0.09, 0.1, 0.2, 0.3, 0.4, 0.5, 0.6, 0.7, 0.8, 0.9, 1, or any combination of two or more thereof.

In some embodiments, the compound has a double perovskite structure.

In some embodiments, a composition is provided, comprising the one or more of the compounds described herein in epitaxial contact with a single-crystalline substrate. The single-crystalline substrate is not particularly limited. In some embodiments, however, the substrate includes a doped SrTiO₃. In some embodiments, the substrate includes Nb-doped SrTiO₃. In some embodiments, the substrate surface includes (001) Nb-doped SrTiO₃.

The method of forming the thin film is not particularly limited, and may suitably include, for example pulsed laser desorption or rf-sputtering of a target compound comprising Ln, B, M, and O. For example, the target compound may have the formula LnBM₂O_{5+δ} and/or LnBM₂O_{5.5+δ}, wherein Ln is a lanthanide, B is an alkali earth metal, M is a transition metal, O is oxygen, and 0≦δ≦1.

In the case wherein pulsed laser desorption is used, it is preferable to use a KrF excimer pulsed laser deposition system with a wavelength 248 nm, but other lasers and wavelengths are possible.

The thickness of the LBCO thin film is not particularly limiting, and may suitably range from about 2 to about 1000 nm and larger. This range includes all values and subranges therebetween, including, for example, about 2, 3, 4, 5, 6, 7, 8, 9, 10, 20, 25, 30, 35, 40, 45, 50, 55, 60, 65, 70, 75, 80, 85, 90, 95, 100, 200, 300, 400, 500, 600, 700, 800, 900, 1000 nm, or any combination of two or more thereof.

In some embodiments, the thin film is removed from the substrate after forming. In other embodiments, the thin film remains on the substrate.

In some embodiments, the thin film may be annealed in an oxygen-containing gas to form an oxygen-annealed film. The temperature of the oxygen annealing is not particularly limited, and may be suitably carried out at a temperature ranging from about 500 to 1000° C. This range includes all values and subranges therebetween, including, for example, about 500, 550, 600, 650, 700, 750, 775, 800, 825, 850, 900, 950, or 1000° C.

The oxygen pressure during the oxygen annealing is not particularly limiting, and may suitably range from about 200 to about 600 Torr oxygen. This range includes all values and subranges therebetween, including, for example, about 200, 300, 350, 375, 400, 425, 450, 500, 550, or 600 Torr oxygen.

The oxygen annealing time is not particularly limiting, and may suitably range from about 5 to about 25 minutes. This range includes all values and subranges therebetween, including, for example, about 5, 6, 7, 8, 9, 10, 11, 12, 13, 15, 16, 17, 18, 19, 20, 21, 22, 23, 24, or 25 minutes.

In some embodiments, the oxygen-annealed film may be further annealed under vacuum. The pressure under which the oxygen-annealed film is vacuum annealed is not particularly limiting and may suitably range from about 1*10⁻⁴ to about 1*10⁻¹² Torr. This range includes all values and subranges therebetween, including, for example, about 1*10⁻⁴, 5*10⁻⁵, 1*10⁻⁵, 5*10⁻⁶, 1*10⁻⁶, 5*10⁻⁷, 1*10⁻⁷, 5*10⁻⁸, 1*10⁻⁸, 5*10⁻⁹, 1*10⁻⁹, 5*10⁻¹⁰, 1*10⁻¹⁰, 5*10⁻¹¹, 1*10⁻¹¹, 5*10⁻¹², or 1*10⁻¹² Torr. In some embodiments, the pressure for vacuum annealing the oxygen-annealed film is lower than about 1*10⁻⁵ Torr.

In some embodiments, the thin film may be annealed under vacuum without first undergoing oxygen annealing. The pressure under which the thin film is vacuum annealed is not particularly limiting and may suitably range from about 1*10⁻⁴ to about 1*10⁻¹² Torr. This range includes all values and subranges therebetween, including, for example, about 1*10⁻⁴, 5*10⁻⁵, 1*10⁻⁵, 5*10⁻⁶, 1*10⁻⁶, 5*10⁻⁷, 1*10⁻⁷, 5*10⁻⁸, 1*10⁻⁸, 5*10⁻⁹, 1*10⁻⁹, 5*10⁻¹⁰, 1*10⁻⁰, 5*10⁻¹¹, 1*10⁻¹¹, 5*10⁻¹², or 1*10⁻¹² Torr. In some embodiments, the pressure for vacuum annealing the thin film is lower than about 1*10⁻⁵ Torr.

The temperature of the vacuum annealing of either the thin film or the oxygen-annealed film is not particularly limited, and may suitably range from about 500 to 1000° C. This range includes all values and subranges therebetween, including, for example, about 500, 550, 600, 650, 700, 750, 775, 800, 825, 850, 900, 950, or 1000° C.

The time of the vacuum annealing of either the thin film or the oxygen-annealed film is not particularly limiting, and may suitably range from about 5 to about 25 minutes. This range includes all values and subranges therebetween, including, for example, about 5, 6, 7, 8, 9, 10, 11, 12, 13, 15, 16, 17, 18, 19, 20, 21, 22, 23, 24, or 25 minutes.

Upon completion of the vacuum annealing of either the thin film or the oxygen-annealed film, the vacuum-annealed film may be cooled to room temperature, or about 25° C. The cooling rate is not particularly limiting and may suitably range from about 1° C./minute to about 15° C./minute. This range includes all values and subranges therebetween, including about 1, 2, 3, 4, 5, 6, 7, 8, 9, 10, 11, 12, 13, 14, or 15° C./minute.

In some embodiments, the compound, composition, and/or thin film exhibit a magnetoelectric response at temperatures ranging from 0° C. or lower to about 45° C. This range includes all values and subranges therebetween, including 0, 1, 2, 3, 4, 5, 10, 15, 20, 25, 30, 35, 40, 45° C., or any combination of two or more thereof. In some embodiments, the compound, composition, and/or thin film exhibit a magnetoelectric response at room temperature. In some embodiments, the compound, composition, and/or thin film exhibit a magnetoelectric response at 25° C.

In another embodiment, a multiferroic device is provided, comprising one or more of the compounds, films, and/or compositions described herein. Non-limiting examples of such devices include nonvolatile memory storage devices, voltage-controlled magnetic anisotropy (VCMA) switches, magnetoelectric memory (MERAM) devices, sensors, spin torque transfer memory devices, low voltage transistors, antennas, dilute magnetic semiconductors, and the like. In some embodiments, the device includes one or more of the compound, composition, and/or thin film described herein in magnetic contact, magnetic field contact, electrical contact, electrical signal contact, electric field contact, thermal contact, or any combination thereof with the device. In some embodiments, the device relies in whole or in part on one or more of a ferroelectric response, magnetoelectric response, ferromagnetic response, ferromagnetic-metallic phase, ferromagnetic-insulating ferroelectric phase, ferroelectric polarization, or magnetoelectric coupling coefficient, or any combination of two or more thereof, of one or more of the compound, composition, and/or thin film described herein for operation.

In some embodiments, the method includes tuning or controlling, in an LBCO thin film, one or more of a ferroelectric response, magnetoelectric response, ferromagnetic response, ferromagnetic-metallic phase, ferromagnetic-insulating ferroelectric phase, ferroelectric polarization, and magnetoelectric coupling coefficient.

In some embodiments, ordered oxygen vacancy structures are provided that were achieved in the highly epitaxial LaBaCo₂O_{5+δ} (LBCO) thin films grown on (001) Nb:SrTiO₃ surface by reduction treatments. Microstructural studies from high resolution x-ray diffraction studies indicate that there is an unusual change of lattice parameter in the film during the oxidation/reduction processes. An ordered oxygen vacancy state, probably associated with the Co-plane, was detected that results in a double perovskite structure accompanied by a very large shift of lattice parameters. High room temperature ferroelectricity and large magnetoelectric response were discovered in the single phase ferromagnetic LBCO thin films and attributed to the ordered oxygen vacancy structure. These findings open a new avenue for the design and synthesis of room temperature multiferroic materials by tailoring their microstructures to facilitate multiferroic coupling.

Complex oxides such as, for example, LBCO thin films, have many important properties. The present inventors have found that by tuning the oxygen vacancy in ordered structures in the complex oxides described herein, their properties can be tuned from ferromagnetic to ferroelectric and multiferroic properties.

In some embodiments, the compounds include LnBM₂O_{5.5+δ} and/or LnBM₂O_{5+δ}, wherein Ln: rare earth lanthanine, B: Ba, Sr, Ca, etc., and M: Co, Mn, Fe, Ni, etc. In the highly epitaxial thin films, the oxygen vacancy will have the ordered structures which can generate the ferroelectricity and multiferroics. These integrated properties can be developed for various important devices.

The existence of oxygen vacancies can be determined in accordance with known methods. For example, which is not intended to be limiting, the existence of oxygen vacancies can be determined using the high resolution reciprocal space maps (RSMs) technique, for example, to determine the lattice structure by measuring the (002), (016), and (106) reflections of the LBCO films described herein.

In some embodiments, ordered oxygen vacancy structures are achieved in the highly epitaxial LaBaCo₂O_{5+δ} (LBCO) thin films grown on Nb:SrTiO₃ surfaces by reduction treatments. Other embodiments may include materials of the formula LnBM₂O_{5.5+δ} (Ln: rare earth lanthanine, B: Ba, Sr, Ca, etc., and M: Co, Mn, Fe, Ni, etc.).

In some embodiments, materials are arranged in highly epitaxial thin films. In some embodiments, these could be a double perovskite structure accompanied by a very large shift of lattice parameters. In some embodiments there is a change in lattice parameters during the oxidation/reduction process. In some embodiments the material has an ordered oxygen vacancy state, associated with the Co-plane.

In some embodiments, the compounds described herein exhibit high room temperature ferroelectricity and large magnetoelectric response were are present in the single phase ferromagnetic LBCO thin films and are attributed to the ordered oxygen vacancy structure.

In some embodiments, provided is a new method for the design and synthesis of room temperature multiferroic materials by tailoring their microstructures to facilitate multiferroic coupling. In some embodiments this tailoring of the microstructures is accomplished through vacuum annealing.

In some embodiments, the vacuum annealing procedure is performed on the LBCO films after their growth by annealing at 800° C. in 400 Torr pure oxygen (Oxygen Annealing) and in vacuum of lower than 1*10−5 Torr (vacuum annealing) for 15 min, respectively, before slowly cooling down to room temperature at the rate of 5° C./min.

Other embodiments of the invention are discussed throughout this application. Any embodiment discussed with respect to one aspect applies to other embodiments as well and vice versa. Each embodiment described herein is understood to be embodiments that are applicable to all embodiments of the invention. It is contemplated that any embodiment discussed herein can be implemented with respect to any device, method, or composition, and vice versa. Furthermore, compounds, systems, compositions, devices, and methods of their making and use are also contemplated herein.

### EXAMPLES

The LBCO thin films were grown on (001) Nb doped SrTiO₃ (Nb:STO) substrate by using a KrF excimer pulsed laser deposition system with a wavelength 248 nm. The growth conditions were determined to be with the energy density of about 2.0 J /cm² at 5 Hz and an oxygen pressure of 250 mTorr at 800° C. The LBCO films after the growth were annealed at 800° C. in 400 Torr pure oxygen (Oxygen Annealing) and in vacuum of lower than 1*10⁻⁵ Torr (vacuum annealing) for 15 min, respectively, before slowly cooling down to room temperature at the rate of 5° C./min. The crystallinity and epitaxial behavior of the LBCO films were characterized by high resolution x-ray diffraction (HRXRD) using PANalytical X'Per MRD. The magnetic properties of the LBCO thin films were evaluated by using a Quantum Design Physical Property (PPMS-9) measurement system. The dielectric properties were measured using an impedance analyzer (Agilent 4980A, USA) in the frequency range of 1 kHz-10MHz. Polarization versus electric field (P-E) hysteresis loops were measured by aixACCT TF-2000 (Germany) at room temperature. Piezoresponse Force Microscopy (PFM) is used to investigate out of plane PFM phase image at room temperature. Magnetoelectric (ME) measurement is done in terms of the variation in the induced voltage by the applied magnetic field at room temperature. Ma, J., et al., Adv Mater 23, 1062-1087, (2011); Wang et al., J Mater Sci 48, 1021-1026, (2013). The sample was put into the DC magnetic field superimposed with a small ac magnetic field δH (RMS value ˜4.2 Oe, 1 kHz) in parallel. The magnetic field is applied parallel to the plane of the thin films (in-plane mode). The voltage signal of the ME response was measured using a lock-in amplifier (SRS Inc. SR850, USA). The waveform of the response voltage was monitored by an oscilloscope (Agilent DSO 5014A, USA) for excluding the false signal, which may arise from the Faraday effect.

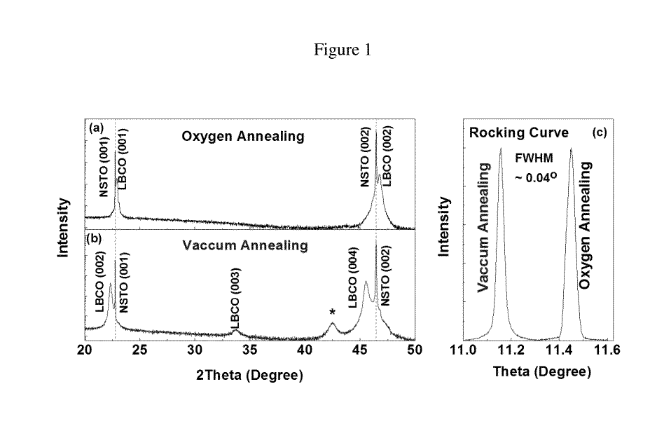

Typical x-ray diffraction θ-2θ scans were performed to study the epitaxial nature and crystallinity of the as-grown LBCO thin film under oxygen and vacuum post annealing treatments. As shown in FIG. 1 (a), only (001) peaks were present in the scan, indicating that the films are growth in c axis orientation. The rocking curve measurement studies reveal that the full width at half maximum (FWHM) is only 0.04° from the (001) reflection, as seen in FIG. 1 (c), indicating the films have excellent single crystal quality. It was noted that the vacuum annealed films show clearly peak shifts to the smaller angles, as seen in FIG. 1(b). It is however unexpected to find that there are essentially no crystallinity changes for the vacuum annealed films, which retain the FWHM value in the rocking curve measurements, as seen in FIG. 1(c). Nevertheless, there are two additional small peaks appeared in the diffraction pattern following the vacuum annealing treatment. The first additional reflection peak appears at 2θ near 34° and can be identified as the (003) reflection from c-axis doubled perovskite LBCO structure. This diffraction is considered as the result from the formation of the ordered oxygen vacancy planes rather than from the A-site ordering since it is very unlikely that the rearrangement of A-site cations to form the A-site ordered structure under such a low temperature vacuum annealing (800° C.). Donner, W. et al., Chem Mater 23, 984-988, (2011). Another additional peak marked with an asterisk is similar to the result from our previous report as the parasitic reflection. Donner, W. et al., Chem Mater 23, 984-988, (2011). However, if it is considered as the results from the atomic shifts from the Co ions which are associated with the oxygen vacancy positions, the atomic position shifts estimated is 0.015 nm. Therefore, this atomic shift will destroy the LBCO crystal local symmetry and may induce the formation of the dipole moments.

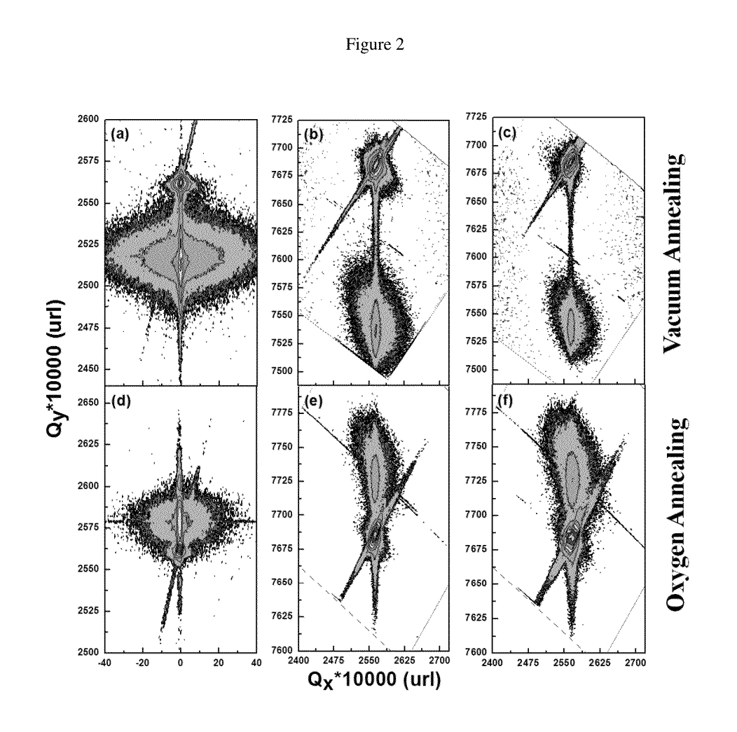

To study systematically the possible oxygen vacancy induced the lattice structure deformation, high resolution reciprocal space maps (RSMs) technique is performed to determine the lattice structure by measuring the (002), (016), and (106) reflections from the LBCO films taken from the vacuum annealed films. A clear picture of the out-of-plane and in-plane lattice parameters of the films can be established by analyzing the relationships in the as-selected reflections. As seen in FIG. 2a, the symmetric reflections of LBCO (002) and Nb:SrTiO₃ (001) overlap each other, suggesting that the (002) plane of LBCO is parallel to the (001) plane of the substrate without any detectable misalignment. The RSMs for the asymmetric reflections of LBCO (106) and Nb:SrTiO₃ (103) can be acquired by using a glancing exit scan. With the same measurement setting but φ rotated 90°, the RSMs around the asymmetric reflections of LBCO (016) and Nb:SrTiO₃ (013) can also be obtained (FIGS. 2b and 2c). According to the Bragg law and the angles' relationship between these crystalline planes²⁶, the lattice parameters of the vacuum annealed LBCO films could be derived, giving a=3.90 Å, b=3.90 Å, and c=7.98 Å. Similarly, the high resolution RSM can also be recorded around (001), (013), and (103) reflections of oxygen annealed LBCO films (FIG. d-f) and the lattice parameters were determined to be a=3.90 Å, b=3.90 Å, and c=3.88 Å. The crystal structures for both films were found to be tetragonal with the tetragonality c/a of 0.995 and 1.023 for oxygen annealed and vacuum annealed films, respectively. In other words, the c-lattice parameter for the vacuum annealing is about 0.22 Å bigger than its normal parameter. Therefore, the unusual lattice deformation after the vacuum annealing may induce various anomalous physical properties, varying from the conductive to insulate, and may result in the generation of the ferroelectricity for vacuum annealed films due to the broken symmetry relationship. Especially, the LaBaCo₂O₆ bulk was found to be noncentrosymmetric due to the fact that chemical pressure from the larger LaO layer extended the CoO₂ square plane which makes it shift to the smaller BaO layer⁹. Therefore, the noncentrosymmetric LBCO crystal structure will result in the formation of the ferroelectricity.

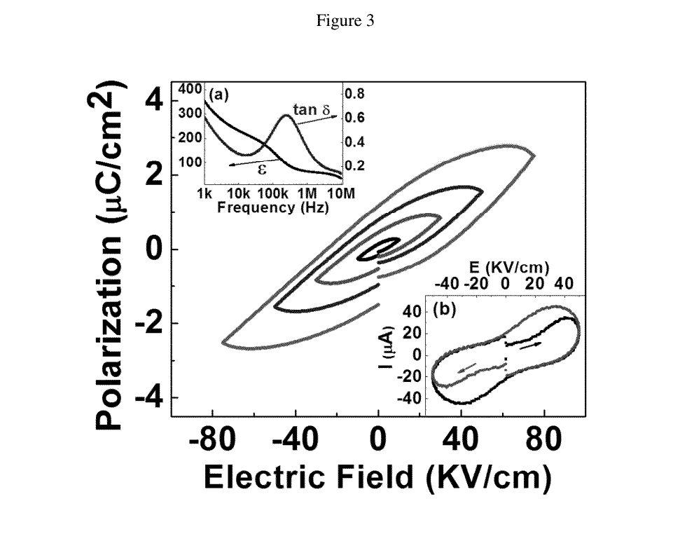

To understand the induced ferroelectric phenomena in ordered oxygen vacancy structures from the annealing treatment, a TF-2000 measurement system was employed to characterize the ferroelectric properties of the films. It is known that a ferroelectric response can be achieved in inhomogeneous system containing easily deformed or disturbed states. Haeni, J. H. et al., Nature 430, 758-761, (2004); Burns, G. & Dacol, F. H., Physical Review B 28, 2527-2530, (1983); Zubko, P., et al., Phys. Rev. Lett. 99, (2007). Therefore, in the vacuum annealed LaBaCo₂O_{5+δ} thin films, the ordered oxygen vacancy structures may generate the local dipoles and thus result in the local polarization. As seen in FIG. 3, the ferroelectric hysteresis loops were obtained from the vacuum annealed films at different electric field, indicating that the vacuum annealed LBCO thin films exhibit a good ferroelectricity. The current peakat I-E curve shown in inset of FIG. 3 (b) corresponds to the ferroelectric domain switching. Yan, H. et al., Journal of Advanced Dielectrics 1, 107-118, (2011). The dielectric properties of LBCO thin film can be seen in the inset of FIG. 3 (a), it is found that the dielectric constant reaches 282 at 1K Hz with the loss tangent being below 0.6. At high frequency (10 MHz), the dielectric loss reduces to 0.14, although the dielectric constant decreases to 28. All of these interesting physical properties of the LBCO thin film indicate that there are good dielectric properties in the ordered oxygen vacancy structural LBCO films.

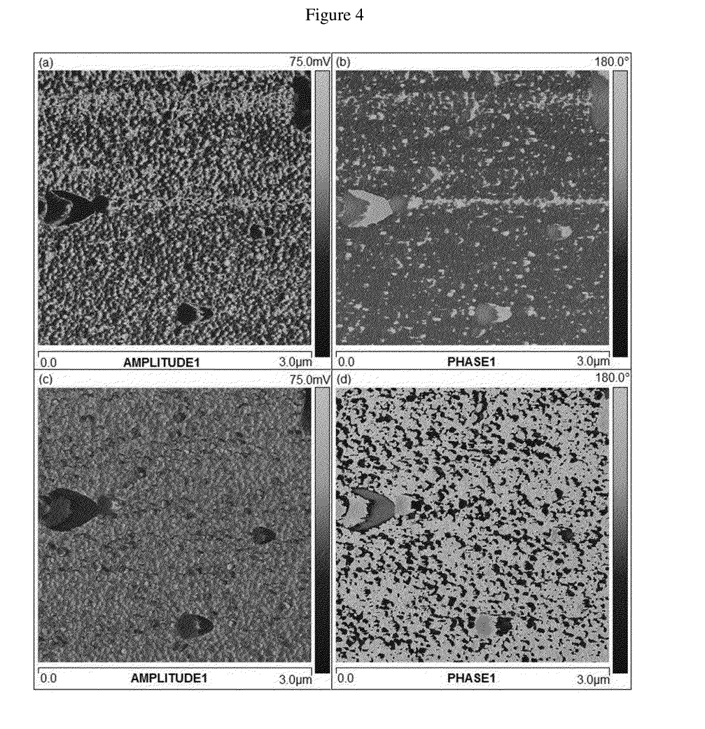

To understand the nature of the ferroelectricity in the LBCO thin films, several experiments were conducted on these films. The ferroelectricity in the vacuum annealed LBCO thin film is also confirmed by the PFM. The out of plane phase response of the vacuum annealed LBCO thin film was measured using the PFM with a +5V and −5V dc bias. A contact mode imaging technique was used with an additional ac voltage of amplitude 5V. It is observed that the vacuum annealed LBCO thin film exhibits an amplitude change and a phase image contrast change with application of different voltage, as shown in FIG. 4. The finding of the ferroelectric properties in the highly epitaxial c-axis double perovskite LBCO thin films indicates that the material properties can be tuned from the expected ferromagnetic to ferroelectric/ferromagnetic coexistence by the defect-engineered structures.

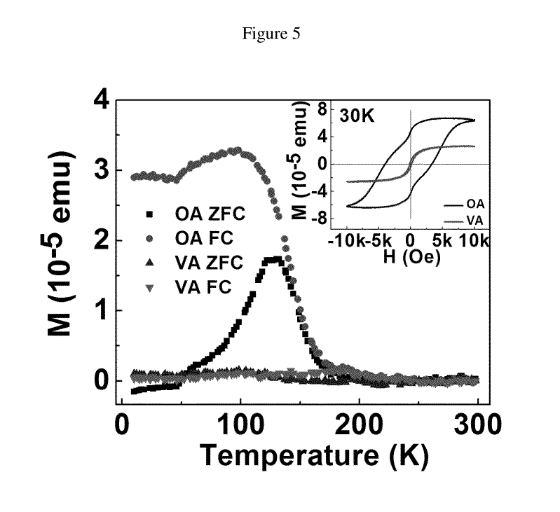

To further investigate the effect of tuning oxygen vacancy structure on physical properties of the film, a Quantum Design physical properties measurement system (PPMS-9) was employed to characterize the magnetizations and the field dependence behavior. As seen in FIG. 5, the as-grown film with the oxygen annealing exhibits good ferromagnetic behavior and large magnetic moment with its Curie temperature of 175 K. There is a ferromagnetic and antiferromagnetic coexistence in the film with its transition temperature of ˜100K. However, it is found rather unexpectedly that its ferromagnetic Curie temperature for the vacuum annealed films is much higher than that with oxygen annealing and without obvious ferromagnetic and antiferromagnetic coexistence behavior in the film. Also, from the field dependence measurements, as seen in the inset of FIG. 5, the remnant magnetic moment with oxygen treatment is much larger than that with vacuum treatment and it exhibits very good magnetic hysteresis loop and ferromagnetic properties. However, the film treated in vacuum shows a slim magnetic hysteresis loop and a smaller remnant magnetic moment.

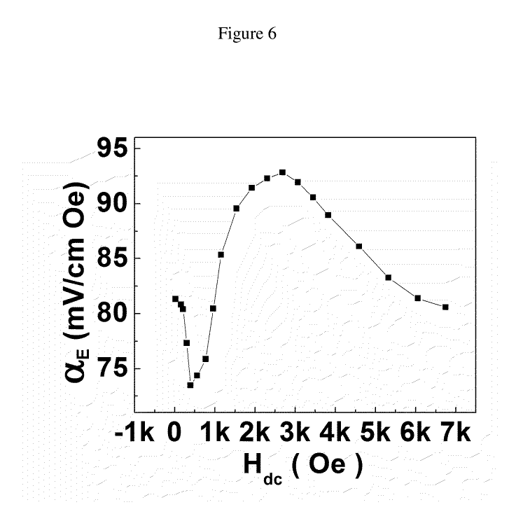

A direct ME response and its dependence as a function of an applied magnetic field were measured. The as-vacuum treated samples did not show detectable magnetoelectric effect at room temperature. However, after the film was magnetized along the in-plane direction by applying 6 kOe magnetic field, the output voltages induced by the ME coupling at room temperature are achieved and recorded by using a lock-in amplifier between the top electrode and the Nb:STO substrate where a dc magnetic field bias H_{dc} superimposed with a small ac magnetic field δH in parallel is applied to the in plane direction of the vacuum annealed film. As shown in FIG. 6, the ME coupling coefficient α_{E} first drops and then increases with increasing dc bias magnetic field H_{dc}, then gradually decreases when the H_{dc} exceeds 2.7 kOe. The maximum value of about 92.8 mV/cm Oe is achieved, which suggests that the room temperature ME coupling coefficient a_{E} is comparable with various multiferroic materials. Eerenstein, W., et al., Nature 442, 759-765, (2006); Eerenstein, W. et al., Science 307, 1203, (2005).

This result suggests that the ordered oxygen vacancy structure can drive an unusual phase transition from the ferromagnetic-metallic (FM-M) phase to ferromagnetic-insulating ferroelectric (FM-I-FE) phases. Especially, the large (in a single phase material) room temperature magnetoelectric response induced by the ordered oxygen vacancy structure found in the vacuum annealed LBCO thin films may open up a new avenue for multiferroic materials' studies and will pave the way for tailoring the material microstructures to tune their properties for the new tunable device development.

Ordered oxygen vacancy structures were achieved in the highly epitaxial LaBaCo₂O_{5+δ} (LBCO) thin films grown on (001) Nb:SrTiO₃ surface by the reduction treatments. Microstructural studies from high resolution x-ray diffraction studies indicate that there is an unusual change of lattice parameter in the film during the oxidation/reduction processes. An ordered oxygen vacancy state, probably associated with the Co-plane, was detected that results in a double perovskite structure accompanied by a very large shift of lattice parameters. High room temperature ferroelectricity and large magnetoelectric response were discovered in the single phase ferromagnetic LBCO thin films and attributed to the ordered oxygen vacancy structure.

These findings open a new avenue for the design and synthesis of room temperature multiferroic materials by tailoring their microstructures to facilitate multiferroic coupling.

While there have been shown and described what are presently believed to be the preferred embodiments of the present invention, those skilled in the art will realize that other and further embodiments can be made without departing from the spirit and scope of the invention described in this application, and this application includes all such modifications that are within the intended scope of the claims set forth herein. All patents and publications mentioned and/or cited herein are incorporated by reference to the same extent as if each individual publication was specifically and individually indicated as having been incorporated by reference in its entirety.

1. A single-crystalline LnBM₂O_{5+δ} or LnBM₂O_{5.5+δ} compound, comprising an ordered oxygen vacancy structure; wherein
Ln is a lanthanide,
B is an alkali earth metal,
M is a transition metal,
O is oxygen, and
0≦δ≦1.

2. The compound of claim 1, wherein Ln is La, Pr, Nd, Sm, or Gd.

3. The compound of claim 1, wherein B is Ba, Sr, or Ca.

4. The compound of claim 1, wherein M is Co, Mn, Fe, or Ni.

5. The compound of claim 1, wherein the compound has a double perovskite structure.

6. A composition, comprising the compound of claim 1 in epitaxial contact with a single-crystalline substrate.

7. The composition of claim 6, wherein the substrate comprises Nb-doped SrTiO₃.

8. A single-crystalline LnBM₂O_{5+δ} or LnBM₂O_{5.5+δ} compound, δ being ≧0 and ≦1, produced by a process comprising:
forming, on a single-crystalline substrate, a thin film comprising Ln, B, M, and O, wherein Ln is a lanthanide, B is an alkali earth metal, M is a transition metal, and O is oxygen;
annealing said thin film in an oxygen-containing gas, to form an oxygen-annealed film and cooling

9. The compound of claim 8, wherein forming said thin film comprises pulsed laser desorption of a target compound comprising Ln, B, M, and O.

10. The compound of claim 8, wherein annealing said thin film in an oxygen-containing gas comprises beating said thin film at 800° C. in 400 Torr oxygen for 15 minutes.

11. The compound of claim 8, wherein annealing said oxygen-annealed film comprises heating said oxygen-annealed film at 800° C. at a pressure lower than 1*10⁻⁵ Torr for 15 minutes.

12. The compound of claim 8, wherein said cooling comprises cooling to 25° C. at a rate of 5° C./minute.

13. A multiferroic device, comprising the compound of claim 1.

14. A method, comprising:
forming, on a single-crystalline substrate, a thin film comprising Ln, B, M, and O, wherein Ln is a lanthanide, B is an alkali earth metal, M is a transition metal, and O is oxygen;
annealing said thin film in an oxygen-containing gas, to form an oxygen-annealed film and cooling;
to produce a single-crystalline LnBM₂O_{5+δ} or LnBM₂O_{5.5+δ} compound, δ being ≧0 and ≦1.

15. The method of claim 14, wherein one or more of a ferroelectric response, magnetoelectric response, ferromagnetic response, ferromagnetic-metallic phase, ferromagnetic-insulating ferroelectric phase, ferroelectric polarization, and magnetoelectric coupling coefficient is tuned or controlled.

16. The method of claim 14, wherein forming said thin film comprises pulsed laser desorption of a target compound comprising Ln, B, M, and O.

17. The method of claim 14, wherein annealing said thin film in an oxygen-containing gas comprises heating said thin film at 800° C. in 400 Torr oxygen for 15 minutes.

18. The method of claim 14, wherein annealing said oxygen-annealed film comprises heating said oxygen-annealed film at 800° C. at a pressure lower than 1*10⁻⁵Torr for 15 minutes.

19. The method of claim 14, wherein said cooling comprises cooling to 25° C. at a rate of 5° C./minute.

20. The method of claim 14, wherein the substrate comprises Nb-doped SrTiO₃.

21-32. (canceled)
